(19) United States
(12) Patent Application Publication
(10) Pub. No.: US 2007/0035036 A1
(43) Pub. Date: Feb. 15, 2007

(54) Semiconductor device, laminated semiconductor device, and wiring substrate

(75) Inventors: Yoshiki Sota, Nara-shi (JP); Kazuo Tamaki, Kitakatsuragi-gun (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka-shi (JP)

(21) Appl. No.: 11/501,010

(22) Filed: Aug. 9, 2006

(30) Foreign Application Priority Data
Aug. 12, 2005 (JP) 2005-235063

(51) Int. Cl. H01L 23/52

(52) U.S. Cl. 257/784

(57) ABSTRACT

The semiconductor device according to the present invention includes a semiconductor chip and a wiring substrate on which a wiring pattern is formed. The wiring pattern includes wire bond terminals being electrically connected, via wires, with pads provided on the semiconductor chip. The wire bond terminals are disposed in a plurality of columns so as to face the pads. When the columns are regarded as the first column to the third column so that the first column is the closest to the pads, the ratio of a pitch between the wire bond terminals belonging to the first column, a pitch between the wire bond terminals belonging to the second column, and a pitch between the wire bond terminals belonging to the third column is 1:2:2. This allows for efficient wiring between the wire bond terminals in a case where wiring with electrolytic plating is impossible. As a result, it is possible to provide a wiring substrate with stable qualities at lower cost.

This non-provisional application claims priority under 35 U.S.C. § 119(a) on Patent Application No. 235063/2005 filed in Japan on Aug. 12, 2005, the entire contents of which are hereby incorporated by reference.

### FIELD OF THE INVENTION

The present invention relates to a semiconductor device, a laminated semiconductor device, and a wiring substrate. The present invention particularly relates to a semiconductor device, a laminated semiconductor device, and a wiring substrate, each of which is suitable for high density packaging.

### BACKGROUND OF THE INVENTION

In accordance with a recent tendency toward downsizing of electric devices and with automation of fabrication processes, there have been widely used semiconductor devices having CSP (Chip Size Package/Chip Scale Package) structures based on QFP (Quad Flat Package) or BGA (Ball Grid Allay).

As signal processes of semiconductor elements included in such semiconductor devices get faster and have higher performance, more number of external terminals are needed. At that time, BGA packages in which external connection terminals are provided on a bottom surface of a semiconductor device in a two-dimensional manner are widely used. One kind of the BGA packages has a structure in which: a semiconductor chip is disposed so that a circuit-formed surface faces upward, is connected with a wiring substrate via wire bonding, and is conducted to external connection terminals via a wiring pattern.

FIG. 6 illustrates a structure of a conventional resin-sealed semiconductor device based on BGA (Ball Grid Allay). This structure is now widely used in BGA semiconductor packages. As illustrated in FIG. 6, a semiconductor device 100 includes: a semiconductor chip 11; Au wires 17; a wiring substrate 18; solder balls 19; and resin 110. The semiconductor chip 11 is mounted on an insulating substrate whose wirings are made of semiconductor copper foil. The semiconductor chip 11 is connected with the wiring substrate 18 via the Au wires 17. The semiconductor chip 11 and the Au wires 17 are sealed by the resin 110. Further, the solder balls 19 acting as external connection terminals to be connected with the semiconductor chip 11 via reflow bonding are provided on the wiring substrate 18 so as to be positioned on a face opposite to a face where the semiconductor chip 11 is mounted.

Further, out of such semiconductor devices, there is a semiconductor device including a plurality of semiconductor chips for the purpose of providing added values such as memory for portable devices and of increasing capacity. An example of such semiconductor device is a multi-chip module in which a plurality of semiconductor chips are mounted so as to be disposed in a lateral manner. However, in the multi-chip module, chips are disposed in a lateral manner, so that it is impossible to fabricate a semiconductor device smaller than the whole area of the semiconductor chips to be mounted.

On the other hand, there is a semiconductor device in which a plurality of semiconductor chips are laminated and mounted so as to further downsize the whole area of the semiconductor chips to be mounted (hereinafter referred to as a “stacked package”). In the stacked package, a plurality of semiconductor chips are laminated, so that packaging density is increased.

The stacked package is disclosed in Document 1 (Japanese Unexamined Patent Publication No. 204720/1999 (Tokukaihei 11-204720; published on Jul. 30, 1999) for example. The semiconductor device disclosed in Document 1 has semiconductor chips mounted on one surface of an electric insulating substrate and has external connection terminals mounted on the other surface in a matrix manner. The semiconductor device has a CSP structure, namely, substantially equal to the size of the semiconductor chip.

In the semiconductor device having such a structure, a first semiconductor chip is die-bonded on a wiring substrate so that a circuit-formed surface of the first semiconductor chip faces upward. Further, a second semiconductor chip is die-bonded on the first semiconductor chip. Further, each of the semiconductor chips is connected with the wiring substrate via Au wires by carrying out wire bonding. Further, the first semiconductor chip, the second semiconductor chip, and the Au wires are sealed with resin by carrying out transfer moulding. Further, solder balls acting as external connection terminals are provided on the wiring substrate so as to be positioned on a surface opposite to a surface where the first semiconductor chip (second semiconductor chip) is provided, and the solder balls are connected with each semiconductor chip via reflow bonding.

Further, as a semiconductor device in which a plurality of semiconductor chips are mounted, other than a semiconductor device in which a plurality of semiconductor chips are laminated inside a single package, there is a semiconductor device in which a plurality of packages are laminated. FIG. 4 illustrates a structure of such a semiconductor device.

As illustrated in FIG. 4, in a case of a package in which a plurality of packages are laminated by connecting external terminals provided outside the areas where semiconductor chips are mounted, in order to maintain electrical conduction between a package and a package provided above or below the package, it is necessary to provide, on an upper surface of a package, lands for mounting a package above the package.

Recently, as electric devices have higher performance, the number of pins of a semiconductor chip mounted on a semiconductor device tends to be increased. If the number of pins of a semiconductor chip is increased, then a conventional semiconductor device has the following arrangements (i) and (ii).

(i) The number of solder balls provided on a packaging substrate is increased, so that a pitch between wire bond terminals gets narrow.

(ii) So far, wire bond terminals are disposed in a column so as to face a plurality of connecting terminals provided on a semiconductor chip mounted on the semiconductor device.

However, the number of wire bond terminals is increased, so that it is impossible to provide the wire bond terminals within a resin-sealed area. Therefore, the arrangement in which the wire bond terminals are disposed in a column is changed to an arrangement in which the wire bond terminals are provided in a staggered manner (hereinafter this arrangement is referred to as “staggered disposition”).

With reference to FIGS. 3(a) and 3(b), the following explains the arrangement in which wire bond terminals are provided in a staggered manner (staggered disposition).

FIGS. 3(a) and 3(b) are plan views illustrating arrangements in which two columns of wire bond terminals are subjected to staggered disposition so as to face a semiconductor chip. FIG. 3(a) illustrates a wiring pattern of a wiring substrate. FIG. 3(b) illustrates a state in which the wiring pattern in FIG. 3(a) is wire-bonded with the semiconductor chip.

As illustrated in FIG. 3(a), a wiring pattern 112 includes first wire bond terminals 13 and second wire bond terminals 15. As illustrated in FIG. 3(b), the first wire bond terminals 13 and the second wire bond terminals 15 are provided in columns so as to face pads 12 of a semiconductor chip 11. Further, the column of the first wire bond terminals 13 is provided closer to the semiconductor chip than the column of the second wire bond terminals 15. Further, the first wire bond terminals 13 and the second wire bond terminals 15 are provided in a staggered manner. Further, the pads 12 provided on the semiconductor chip 11 are electrically connected with the first wire bond terminals 13 and the second wire bond terminals 15 via bonding wires 17.

Further, in the wiring pattern 112, drawn-out wirings 16 and 16′ are drawn out of the first wire bond terminals 13 and the second wire bond terminals 15, respectively. Out of the drawn-out wirings from the wire bond terminals, the drawn-out wirings 16 from the first wire bond terminals 13 provided on the center side of a package are drawn out toward the center of the package. On the other hand, the drawn-out wirings 16′ from the second wire bond terminals 15 provided on the outer side of the package are drawn out toward the outside of the package.

Generally, a substrate to be subjected to electrolytic plating needs an electrolytic-plating line for power supply. In the wiring pattern 112, the drawn-out wirings 16 are drawn out toward the center of the package. On a surface where the wire bond terminals are formed, there is no area via which the drawn-out wirings 16 are drawn out of the first wire bond terminals 13. As such, the drawn-out wirings 16 are extended to a ball land surface (surface on which solder balls are formed) via a VIA hole or VIA holes and then are extended on the ball land surface side.

However, in a case of a semiconductor device package including a semiconductor chip having many pins, a pitch between ball lands tends to be narrow. As a result, the number of wirings which can be provided between ball lands is limited. Therefore, if the number of pins in the semiconductor chip is increased, it is impossible to provide electrolytic-plated drawn-out wirings to be connected with the circumferential part of the package.

To be specific, compared with a necessary pitch of the wire bond terminals, the possible design rule of a wiring pattern of a wiring substrate is rough. As a result, in a case where a wire bond terminal keeps such width as to allow wire bonding, when the wire bond terminals are disposed in a column, a wire bond angle tends to be increased. Further, in a case where the wire bond angle keeps such angle as to allow wire bonding, it is necessary to provide a large distance between the semiconductor chip and the wire bond terminals. Note that, the wire bond angle is defined so that: the wire bond angle is 0° when the wire bond is at an angle of 90 degrees with respect to a surface of a chip edge and the wire bond angle becomes larger as the wire bond is inclined toward the surface of the chip edge.

In the conventional semiconductor device, a possible pitch between the wire bond terminals tends to range from two times to four times as large as a pitch between pads provided on a semiconductor chip. As the wire bond angle becomes larger, a distance between wires becomes small. Therefore, if the semiconductor chip is sealed with resin, wire sweep may occur. As a result, the possibility of short between wires becomes higher.

Therefore, it is necessary to provide the wire bond terminals so that the wire bond angle becomes smaller. In order to make the wire bond angle smaller, it is preferable to provide the wire bond terminals so that the pitch between pads on the semiconductor chip is close to (substantially similar to) the pitch between wire bond terminals on a substrate.

As described above, in a case where the pitch between the pads on the semiconductor chip is close to the pitch between the wire bond terminals and the wire bond angle is small, the wire bond terminals are provided comparatively near the semiconductor chip, so that it is possible to reduce the length of a wire.

Further, if it is possible to reduce the length of the wire, then it is possible to make the resin-sealed area small with respect to the size of the semiconductor chip. This is effective for a package such as a package-laminated package, in which it is necessary to provide lands for mounting an upper package outside the resin-sealed area.

Therefore, in order to cause the pitch between the pads on the semiconductor chip to be substantially identical with the pitch between the wire bond terminals, there are adopted such methods as (i) a method in which the pitch between the wire bond terminals is narrowed so as to be substantially identical with the pitch between the pads on the semiconductor chip or (ii) a method in which the wire bond terminals are provided so that some terminals are closer to/farther from the semiconductor chip and thus the pitch is narrowed.

If the pitch between the pads on the semiconductor chip is wide enough, it is possible to provide the wire bond terminals while a necessary wire bond area is maintained. However, recently, as semiconductor chips get smaller and have higher performance, the pitch between the pads on the semiconductor chip becomes extremely small. As such, as to a semiconductor device including such a semiconductor chip, it is impossible to cause the pitch between the wire bond terminals to be substantially as narrow as the pitch between the pads on the semiconductor chip.

On the other hand, when the wire bond terminals are provided so that some terminals are closer to/farther from the semiconductor chip (namely, provided in a staggered manner), it is possible to provide the wire bond terminals so that the pitch between the wire bond terminals is close to the pitch between the pads on the semiconductor chip.

One of the most simple arrangements of such a staggered disposition is the disposition illustrated in FIGS. 3(a) and 3(b), in which the wire bond terminals are disposed in two columns. At that time, when the pitch between the wire bond terminals on the wiring substrate is two times or so as large as the pitch between the pads on the semiconductor chip, it is possible to cause wires extending from the semiconductor chip to the wire bond terminals to have little wire bond angle.

To be more specific, the following explains a case where a pitch between pads on a semiconductor chip is 60 μm and there is used a wiring substrate in which wiring is possible as long as line/space (ratio of the line width to the space width) is not less than 20 μm/20 μm. If two columns of the wire bond terminals are disposed in a staggered manner on the semiconductor chip, then a pitch between the wire bond terminals on each column is 120 μm and the width of each wire bond terminal is 100 μm. The pitch between the wire bond terminals and the width of each wire bond terminal allows for conventional wire bonding.

However, with the arrangement, the drawn-out wirings from the wire bond terminals cannot connect the wire bond terminals. As such, in the staggered disposition illustrated in FIGS. 3(a) and 3(b), the drawn-out wirings 16 are drawn out of the wire bond terminals (first wire bond terminals 13) on a column closer to the semiconductor chip 11 toward the semiconductor chip 11 (toward the center of the package), while the drawn-out wirings 16′ are drawn out of the wire bond terminals (second wire bond terminals 15) on a column father from the semiconductor chip 11 toward the circumference of the semiconductor chip 11. If the semiconductor device is designed so that a drawn-out wiring passes between the wire bond terminals, then the width of the wire bond terminal is narrowed to 60 μm. However, if the width of the wire bond terminals is narrowed to 60 μm, it is difficult to perform wire bonding between the pads of the semiconductor chip and the wire bond terminals. As a result, it is impossible to form a package. Therefore, as illustrated in FIG. 3(a), the drawn-out wirings from the first wire bond terminals 13 provided inside the package are drawn out toward the semiconductor chip 11, while the drawn-out wirings from the second wire bond terminals 15 provided near the outside are drawn out toward the outside. Wirings drawn out of the wire bond terminals are connected with the external terminal lands.

At that time, the drawn-out wirings 16 drawn out of the first wire bond terminals 13 provided toward the semiconductor chip 11 (toward the center of the package) are connected with external connecting lands provided near the center of the package. However, in order to cause the drawn-out wirings 16 to be subjected to electrolytic plating, it is necessary to draw out the drawn-out wirings 16 to the circumference of the package. If the number of external terminals is large, it is necessary to reduce the pitch between external terminals. As a result, in a case of a package whose pitch between external terminals is small, the number of wirings which can be provided between the lands for connection with external terminals is limited, and therefore it is impossible to draw out the drawn-out wirings from all the wire bond terminals to the circumference of the package.

At that time, examples of possible methods include (i) a method in which electroless plating having unstable elements is performed instead of electrolytic plating having stable plating quality and plated drawn-out wirings are not used, (ii) a method in which the number of wiring layers on a substrate is increased and a part where drawn-out wirings are provided is maintained, and (iii) an etch-back method in which electrolytic plating lines are partially shorted and shorted areas are removed via etching after metal plating. However, such methods bring increase in costs and therefore unsuitable for fabricating substrates and packages with low costs.

As described above, in a wiring pattern in which two columns of the wire bond terminals are provided in a staggered manner so as to be positioned along with the circumference of the semiconductor chip, drawn-out wirings from the wire bond terminals provided closest to the semiconductor chip are extended to a back surface of the wiring substrate via a VIA hole or VIA holes or other components and are connected with external terminals. At that time, in a case of a package whose pitch between external terminals is small, the number of wirings provided between lands for connection with external terminals is limited, so that it is difficult to draw out the drawn-out wirings from all the wire bond terminals.

### SUMMARY OF THE INVENTION

The present invention was made in view of the foregoing problems. An object of the present invention is to provide (i) a wiring substrate with stable qualities, which is made inexpensive by efficiently connecting the wire bond terminals at a time when electrolytic plating is impossible, and (ii) a semiconductor device including the wiring substrate.

In view of the foregoing object, the inventors of the present invention have diligently studied and found that: when wire bond terminals are provided in a specific disposition, it is possible to efficiently draw out drawn-out wirings from wire bond terminals provided closest to a semiconductor chip. With the finding, the inventors of the present invention have made the present invention.

Namely, in order to solve the foregoing problems, the semiconductor device according to the present invention is a semiconductor device, including a semiconductor element and a wiring substrate on which a wiring pattern is formed, said wiring pattern including wire bond terminals electrically connected, via bonding wires, with connecting terminals provided on the semiconductor element, said wire bond terminals being provided in a plurality of columns so as to face the connecting terminals, wherein when the columns are regarded as a first column to an nₜₕ column (n is an integer of 3 or greater) so that the first column is closest to the connecting terminals, a ratio between pitches of wire bond terminals belonging to an n-2ₜₕ column, an n-1ₜₕ column, and an nₜₕ column, respectively, is 1:2:2.

In the semiconductor device according to the present invention, the semiconductor element is conducted to the wiring pattern via the wire bond terminals which are electrically connected, via the bonding wires, with the connecting terminals provided on the semiconductor element. The drawn-out wirings are drawn out of the wire bond terminals so as to be connected with external connecting terminals.

So far, the arrangement in which a plurality of wire bond terminals are disposed in a plurality of columns so as to face a plurality of connecting terminals is generally an arrangement in which the wire bond terminals are provided in a staggered manner so as to face the connecting terminals.

In the conventional arrangement in which the wire bond terminals are disposed in a staggered manner, drawn-out wirings drawn out of the wire bond terminals provided closest to the semiconductor element are extended to the rear surface of the wiring substrate and extended to the circumference of the semiconductor device. When the semiconductor device has small pitch between external terminals, the number of wirings which can be provided between lands for connection with the external terminals is limited, so that it is difficult to draw out drawn-out wirings from all the wire bond terminals.

However, with the arrangement, the ratio of a pitch of the wire bond terminals belonging to the n-2ₜₕ column, a pitch of the wire bond terminals belonging to the n-1ₜₕ column, and a pitch of the wire bond terminals belonging to the nₜₕ column is 1:2:2. Therefore, the distance between the wire bond terminals belonging to the n-2ₜₕ column, the distance between the wire bond terminals belonging to the n-1ₜₕ column, and the distance between the wire bond terminals belonging to the nₜₕ column are widened, so that it is possible to draw out a plurality of drawn-out wirings (three or more drawn-out wirings) to a space between the wire bond terminals. Namely, with the arrangement, unlike the conventional arrangement in which wire bond terminals are provided in a staggered manner, it is possible to provide a space between the wire bond terminals, through which space a plurality of drawn-out wirings pass.

Therefore, with the arrangement, it is possible to efficiently draw out, to the circumference of the semiconductor device, drawn-out wirings from the wire bond terminals provided closest to the connecting terminals. As a result, it is possible to fabricate a wiring substrate with stable qualities at lower cost.

Further, the laminated semiconductor device according to the present invention has a plurality of the semiconductor devices laminated therein. At that time, the wiring substrate includes a land section for allowing electrical connection with the external connecting terminals, and the land section is provided so as to allow conduction of the laminated semiconductor devices. The semiconductor device according to the present invention is effectively applicable to the laminated semiconductor device.

In order to achieve the foregoing object, the wiring substrate according to the present invention is a wiring substrate, having a wiring pattern formed thereon, said wring pattern including wire bond terminals for being electrically connected with connecting terminals provided on a semiconductor element mounted on the wiring substrate, said wire bond terminals being provided on the wiring substrate in a plurality of columns so as to face the connecting terminals, wherein when the columns are regarded as a first column to an nₜₕ column (n is an integer of 3 or greater) so that the first column is closest to the connecting terminals, ratio of pitches of wire bond terminals belonging to an n-2ₜₕ column, an n-1ₜₕ column, and an nₜₕ column, respectively, is 1:2:2.

With the arrangement, it is possible to efficiently draw out, to the circumference of the semiconductor device, the drawn-out wirings from the wire bond terminals provided closest to the connecting terminals. As a result, it is possible to fabricate the wiring substrate with stable qualities at lower cost.

For a fuller understanding of the nature and advantages of the invention, reference should be made to the ensuing detailed description taken in conjunction with the accompanying drawings.

### BRIEF DESCRIPTION OF THE DRAWINGS

FIG. 1(a) illustrates the location of wire bond terminals on a wiring substrate in a semiconductor device according to an embodiment of the present invention so as to illustrate a wiring pattern of the wiring substrate.

FIG. 1(b) illustrates a state in which the wiring pattern in FIG. 1(a) is wire-bonded with a semiconductor chip.

FIG. 2(a) is a plan view illustrating an arrangement in which three columns of wire bond terminals are disposed in a staggered manner. FIG. 2(a) is a wiring pattern of a wiring substrate.

FIG. 2(b) illustrates a state in which the wiring pattern in FIG. 2(a) is wire-bonded with a semiconductor chip.

FIG. 3(a) is a plan view illustrating an arrangement in which two columns of wiring bond terminals are disposed in a staggered manner. FIG. 3(a) illustrates a wiring pattern of a wiring substrate.

FIG. 3(b) illustrates a state in which a wiring pattern in FIG. 3(a) is wire-bonded with a semiconductor chip.

FIG. 4 is a cross sectional view schematically illustrating the structure of a semiconductor device in which a plurality of packages are laminated.

FIG. 5 is a plan view illustrating the location of wire bond terminals on a wiring substrate in a semiconductor device according to another embodiment of the present invention.

FIG. 6 is a cross sectional view schematically illustrating the structure of a conventional semiconductor device.

### DESCRIPTION OF THE EMBODIMENTS

### Embodiment 1

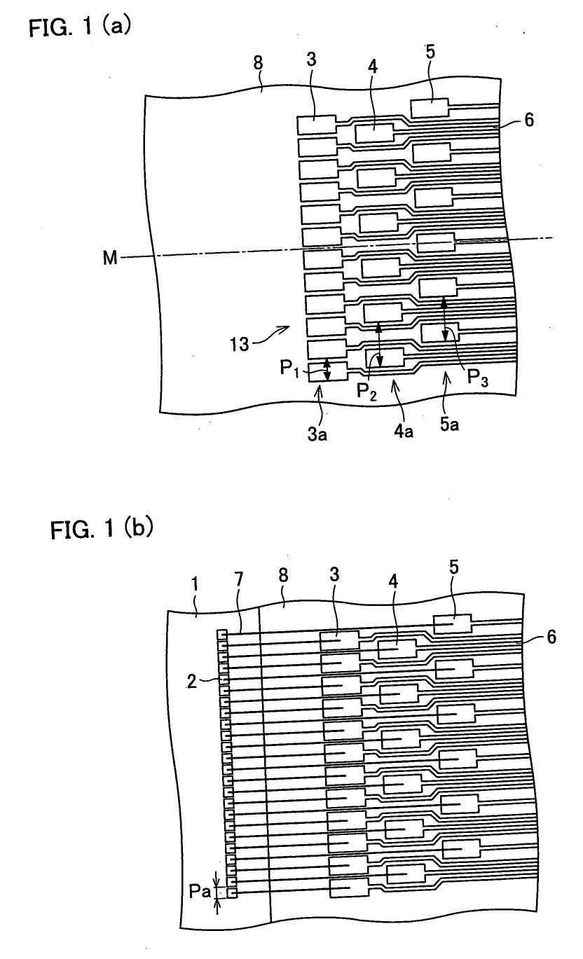

With reference to FIGS. 1(a) and 1(b), the following explains an embodiment of the present invention. FIGS. 1(a) and 1(b) illustrate the location of wire bond terminals on a wiring substrate in a semiconductor device according to the present embodiment. FIG. 1(a) illustrates a wiring pattern of the wiring substrate. FIG. 1(b) illustrates a state in which the wiring pattern in FIG. 1(a) is wire-bonded with a semiconductor chip. Note that, FIGS. 1(a) and 1(b) illustrate a case where three columns of wire bond terminals are provided so as to be positioned along with the circumference of a semiconductor chip. However, the present invention is not limited to this case.

As illustrated in FIGS. 1(a) and 1(b), the semiconductor device according to the present invention (hereinafter referred to as “the present semiconductor device”) includes a semiconductor chip (semiconductor element) 1 and a wiring substrate 8. The semiconductor chip 1 is provided with a plurality of pads (connecting terminals) 2. Further, a wiring pattern 13 is formed on the wiring substrate 8.

The wiring pattern 13 includes: first wire bond terminals (wire bond terminals which belong to n-2ₜₕ column) 3; second wire bond terminals (wire bond terminals which belong to n-1ₜₕ column) 4; and third wire bond terminals (which belong to nₜₕ column) 5. As illustrated in FIGS. 1(a) and 1(b), the first wire bond terminals 3, the second wire bond terminals 4, and the third wire bond terminals 5 are disposed in columns so as to face the pads 2 provided on the semiconductor chip 1. Further, a column 3a (first column) of the first wire bond terminals 3, a column 4a (second column) of the second wire bond terminals 4, and a column 5a (third column) of the third wire bond terminals 5 are disposed in this order so that the column 3a is the closest to the pads 2.

The first wire bond terminals 3, the second wire bond terminals 4, and the third wire bond terminals 5 are disposed with predetermined pitches P₁, P₂, and P₃, respectively. Further, the ratio of (a) the pitch P₁ of the first wire bond terminals 3 which belong to the column 3a, (b) the pitch P₂ of the second wire bond terminals 4 which belong to the column 4a, and (c) the pitch P₃ of the third wire bond terminals 5 which belong to the column 5a is 1:2:2.

Further, the ratio of the number of the wire bond terminals which belong to the first column 3a, the number of the wire bond terminals which belong to the second column 4a, and the number of the wire bond terminals which belong to the third column 5a (the first wire bond terminals 3, the second wire bond terminals 4, and the third wire bond terminals 5) is 2:1:1.

Further, in the present semiconductor device, drawn-out wirings 6 are drawn out of the first wire bond terminals 3, the second wire bond terminals 4, and the third wire bond terminals 5, respectively. The drawn-out wirings 6 from the wire bond terminals are drawn out toward the outside of a package.

In a conventional semiconductor device, in a case where the wire bond terminals are disposed in a staggered manner, front wire bond terminals and rear wire bond terminals are disposed alternately so that wire bonds between the semiconductor chip and the wire bond terminals do not overlap each other (do not intersect each other). With the arrangement, drawn-out wirings from the wire bond terminals provided closest to the semiconductor chip are drawn out toward the semiconductor chip, and are extended to the rear surface of the wiring substrate via a VIA hole or VIA holes or other components, and are connected with external terminals. At that time, in a case of a package whose pitch between the external terminals is small, the number of wirings provided between lands for connection with the external terminals is limited, so that it is difficult to draw out the drawn-out wirings from all the wire bond terminals.

On the other hand, in the present semiconductor device, as illustrated in FIGS. 1(a) and 1(b), the ratio of the number of the wire bond terminals which belong to the column 3a, the number of the wire bond terminals which belong to the column 4a, and the number of the wire bond terminals which belong to the column 5a is 2:1:1. Further, the ratio of the pitch between the wire bond terminals which belong to the column 3a, the pitch between the wire bond terminals which belong to the column 4a, and the pitch between the wire bond terminals which belong to the column 5a is 1:2:2. With the arrangement, the distance between the second wire bond terminals 4 which belong to the column 4a, and the distance between the third wire bond terminals which belong to the column 5a are widened and therefore it is possible to provide a plurality of drawn-out wirings (3 or more drawn-out wirings) in a space between the wire bond terminals. Namely, unlike the conventional semiconductor device, the location of the wire bond terminals in the present semiconductor device allows for providing the space through which the plurality of drawn-out wirings pass. As such, in the present semiconductor device, it is possible to efficiently draw out, to the circumference of the package, the drawn-out wirings from the wire bond terminals provided closest to the semiconductor chip (the first wire bond terminals 3 which belong to the column 3a). As a result, it is possible to fabricate a wiring substrate with stable qualities at lower cost.

Further, in the wiring pattern on the present semiconductor device, the wire bond terminals which belong to the second column to the n^{th} column, respectively, are disposed so that: when a straight line is drawn between wire bond terminals which belong to the first column and are adjacent to each other, the line passes through only one wire bond terminal which belongs to one of the second column to the nₜₕ column. Namely, as illustrated in FIG. 1(a), in the wiring pattern 13, the third wire bond terminals 5 are disposed so that: when a straight line M is drawn between the first wire bond terminals 3 which belong to the column 3a and are adjacent to each other, the straight line M passes through only one wire bond terminal 5 which belongs to the column 5a. In a case where the distance between each of the wire bond terminals 3 and the straight line M is equal to a pitch between the connecting terminals on the semiconductor element, each of wires 7 electrically connected with the wire bond terminals (the first wire bond terminals 3, the second wire bond terminals 4, and the third wire bond terminals 5) which belong to the columns 3a to 5a do not overlap each other.

Note that, the wiring pattern in the present semiconductor device may be arranged as follows: the wire bond terminals belonging to each of the second column through the n^{th} column are disposed so that when a straight line is drawn between the wire bond terminals which belong to the first column and adjacent to each other, there exists at least one straight line which passes through wire bond terminals belonging to the second column to the n^{th} column, respectively. This arrangement also causes less overlapping (intersecting) of bonding wires electrically connected with the wire bond terminals.

Further, in the wiring pattern 13, the pads 2 are disposed with a predetermined pitch Pa. The wire bond terminals belonging to the columns 4a or 5a are disposed so as to be shifted, by the pitch Pa, with respect to the first wire bond terminals 3 belonging to the column 3a. As a result, the pitch between the wires 7 is comparatively close to the pitch between the pads 2. As such, it is possible to shorten the wires 7. As a result, the first wire bond terminals 3, the second wire bond terminals 4, and the third wire bond terminals 5 are disposed comparatively close to the semiconductor chip 1, so that it is possible to downsize the semiconductor device.

Using a comparative example in which three columns of wire bond terminals are disposed in a staggered manner from the side of a semiconductor chip, the following further details the effect of the present semiconductor device.

First, the following explains the comparative example in which three columns of the wire bond terminals are disposed in a staggered manner. It is general that when wire bond terminals are disposed in a staggered manner, front wire bond terminals and rear wire bond terminals are disposed alternately so that wire bonds from a semiconductor chip do not overlap each other (do not intersect each other). It is necessary to provide a space between wire bond terminals in a column closest to the outside of the package so that wirings from inward wire bond terminals pass through the space. Therefore, in a case where the wire bond terminals are disposed in a staggered manner, the wire bond terminals closest to the outside of the package are disposed so as to be in a front column and a rear column. This brings three-column staggered disposition.

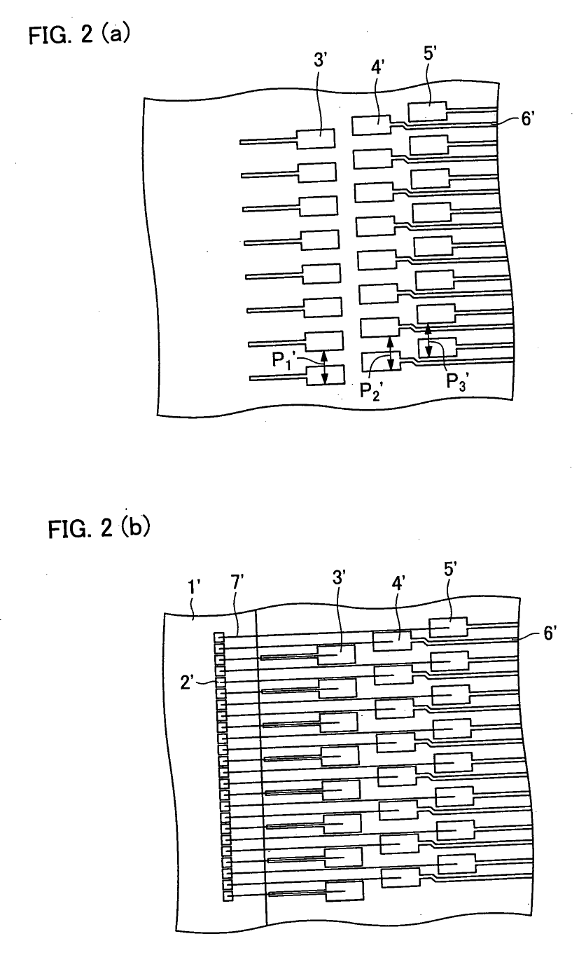

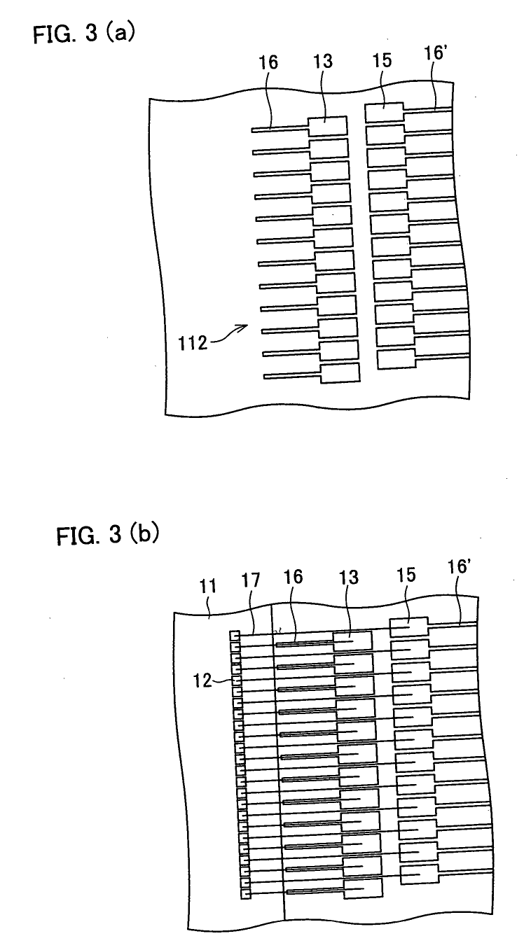

Namely, the arrangement in which three columns of the wire bond terminals are disposed from the side of the semiconductor chip in a staggered manner is illustrated in FIGS. 2(a) and 2(b). FIGS. 2(a) and 2(b) are plan views illustrating an arrangement in which three columns of wire bond terminals are disposed in a staggered manner. FIG. 2(a) illustrates a wiring pattern of a wiring substrate. FIG. 2(b) illustrates a state in which the wiring pattern in FIG. 2(a) is wire-bonded with a semiconductor chip.

As illustrated in FIGS. 2(a) and 2(b), a wiring pattern 13′ includes first wire bond terminals 3′, second wire bond terminals 4′, and third wire bond terminals 5′. As illustrated in FIG. 2(b), the first wire bond terminals 3′, the second wire bond terminals 4′, and the third wire bond terminals 5′ are disposed in columns so as to face pads 2′ provided on a semiconductor chip 1′. Further, a column 3a′ of the first wire bond terminals 3′, a column 4a′ of the second wire bond terminals 4′, and a column 5a′ of the third wire bond terminals 5′ are disposed in this order so that the column 3a′ is the closest to the pads 2′.

The first wire bond terminals 3′, the second wire bond terminals 4′, and the third wire bond terminals 5′ are disposed with a predetermined pitches P₁′, P₂′, and P₃′, respectively. Further, the ratio of (a) the pitch P₁′ of the first wire bond terminals 3′ belonging to the column 3a′, (b) the pitch P₂′ of the second wire bond terminals 4′ belonging to the column 4a′, and (c) the pitch P₃′ of the third wire bond terminals 5′ belonging to the column 5a′ is 1:1:1.

Further, the ratio of the number of the wire bond terminals belonging to the column 3a′, the number of the wire bond terminals belonging to the column 4a′, and the number of the wire bond terminals belonging to the column 5a′ (the number of the first wire bond terminals 3′, the number of the second wire bond terminals 4′, and the number of the third wire bond terminals 5′) is 1:1:1.

Using concrete numerals as examples, the following explains the arrangement illustrated in FIGS. 2(a) and 2(b). The following explains a case where a pad pitch of the semiconductor chip 1′ is 60 μm and there is used a wiring substrate in which wiring is possible as long as line/space (ratio of the line width to the space width) is not less than 20 μm/20 μm.

If the pitch of the pads 2′ of the semiconductor chip 1′ is 60 μm, then it is necessary to dispose wire bond terminals so that the pitch between the wire bond terminals is also 60 μm. In a case where two columns of the wire bond terminals are disposed in a staggered manner, assuming that line/space of a possible wiring rule of a substrate is 20 μm/20 μm, the width of the wire bond terminal is 100 μm which is a numeral allowing wire-bonding. However, in the case where two columns of the wire bond terminals are disposed in a staggered manner, drawn-out wirings which can be extended to the outside of the wire bond terminals are only wirings connected with the wire bond terminals in the column positioned on an outer part of the package (in a case where wirings on a ball land surface are not considered).

Next, a case where three columns of the wire bond terminals are disposed in a staggered manner is considered. As illustrated in FIGS. 2(a) and 2(b), the ratio of the number of the wire bond terminals belonging to the inner column (column 3a′), the number of the wire bond terminals belonging to the central column (column 4a′), and the number of the wire bond terminals belonging to the outer column (column 5a′) (the number of the first wire bond terminals 3′, the number of the second wire bond terminals 4′, and the number of the third wire bond terminals 5′) is 1:1:1. In the arrangement, in order to draw out, toward the outside of the package, wirings drawn out from all the wire bond terminals, it is necessary to cause two wirings to pass between the wire bond terminals in the outer column (column 5a′).

However, in the wiring substrate in which wiring is possible as long as line/space (ratio of the line width to the space width) is not less than 20 μm/20 μm, the pitch P₃′ between the third wire bond terminals 5′ is 180 μm which is three times as large as the pitch between the pads 2′. As a result, the space between the third wire bond terminals 5′ is 80 μm. If the space between the third wire bond terminals 5′ is 80 μm, only one drawn-out wiring whose line/space is 20 μm/20 μm can be provided. As a result, in the arrangement illustrated in FIGS. 2(a) and 2(b), it is possible to provide a space between the wire bond terminals so that a drawn-out wiring can be drawn out via the space from the second wire bond terminals 4′ of the central column (column 4a′), but it is impossible to provide a space via which two wirings (one from the second wire bond terminals 4′ and the other from the first wire bond terminals 3′ of the inner column (column 3a′)) can be drawn out. As a result, only the drawn-out wirings from the first wire bond terminals 3′ belonging to the inner column (column 3a′) are drawn out toward the semiconductor chip 1′, so that the drawn-out wirings from all the wire bond terminals cannot be efficiently drawn out toward the circumference of the package.

Therefore, the drawn-out wirings from the first wire bond terminals 3′ of the inner column (column 3a′) are drawn out toward the semiconductor chip 1′, while the drawn-out wirings from the wire bond terminals of the central column (column 4a′) and the outer column (column 5a′) are drawn out toward the outside (circumference of the package). However, the drawn-out wirings from the wire bond terminals disposed closest to the semiconductor chip 1′ are extended to the rear surface of the wiring substrate via a VIA hole or VIA holes or the similar components, and are connected with external terminals. Namely, it is necessary to draw out the drawn-out wirings from the first wire bond terminals 3′ of the inner column (column 3a′) toward the outside (circumference of the package) and to provide drawn-out wirings for electrolytic plating between external terminal lands. At that time, in a case of a package whose pitch between external terminals is small, the number of the wirings which can be provided between the lands for connection with the external terminals is limited, so that it is difficult to draw out the drawn-out wirings from all the wire bond terminals.

On the other hand, as illustrated in FIG. 1, in the present semiconductor device, even when three columns of the wire bond terminals are provided, it is possible to efficiently draw out the drawn-out wirings from all the wire bond terminals toward the circumference of the package. Using concrete numerals as examples, the following explains the arrangement illustrated in FIGS. 1(a) and 1(b). Note that, the following is a case where the pad pitch of the semiconductor chip 1 is 60 μm and there is used a wiring substrate in which wiring is possible as long as line/space (ratio of the line width to the space width) is not less than 20 μm/20 μm.

If the pitch between the wire bond terminals of the wiring substrate is about twice as large as the pad pitch of the semiconductor chip, it is possible to cause the wirings from the semiconductor chip to the wiring bond terminals to have little angles. As a result, the pitch P₁ between the first wire bond terminals 3 belonging to the column 3a is set to 120 μm which is twice as large as the pad pitch of the semiconductor chip 1. Further, as illustrated in FIGS. 1(a) and 1(b), the number of the first wire bond terminals 2 belonging to the column 3a is 12.

As described above, in the present semiconductor device, the ratio of (a) the pitch P₁ of the first wire bond terminals 3 which belong to the column 3a, (b) the pitch P₂ of the second wire bond terminals 4 which belong to the column 4a, and (c) the pitch P₃ of the third wire bond terminals 5 which belong to the column 5a is 1:2:2. Further, the ratio of the number of the wire bond terminals which belong to the column 3a, the number of the wire bond terminals which belong to the column 4a, and the number of the wire bond terminals which belong to the column 5a (the first wire bond terminals 3, the second wire bond terminals 4, and the third wire bond terminals 5) is 2:1:1.

Therefore, the number of the second wire bond terminals 4 which belong to the column 4a is 6 and the pitch P₂ between the second wire bond terminals 4 is 240 μm. Further, the number of the third wire bond terminals 5 which belong to the column 5a is also 6 and the pitch P₃ between the third wire bond terminals 5 is 240 μm.

In the arrangement illustrated in FIGS. 1(a) and 1(b), in order to draw out the drawn-out wirings from all the wire bond terminals toward the circumference of the package, it is necessary to arrange the space between the third wire bond terminals 5 so that three drawn-out wirings can be drawn out of the space.

As described above, the pitch P₃ between the third wire bond terminals 5 belonging to the column 5a is 240 μm, so that the space between the third wire bond terminals 5 is 140 μm. In the wiring substrate in which wiring is possible as long as line/space (ratio of the line width to the space width) is not less than 20 μm/20 μm, if the space between the third wire bond terminals 5 is 140 μm, it is possible to draw out three drawn-out wirings 6. As a result, in the present semiconductor device, it is possible to draw out the drawn-out wirings from all the wire bond terminals toward the outside of the package.

Namely, in a case where three columns of the wire bond terminals are provided so that the drawn-out wirings from the wire bond terminals are drawn out toward the circumference of the package, by setting the numbers of the wire bond terminals so that the ratio of the numbers of the three columns is 2:1:1 from the inner column (column 3a) and by setting the pitches of the wire bond terminals belonging to the three columns to 1:2:2, it is possible to efficiently provide the drawn-out wirings toward the circumference of the package.

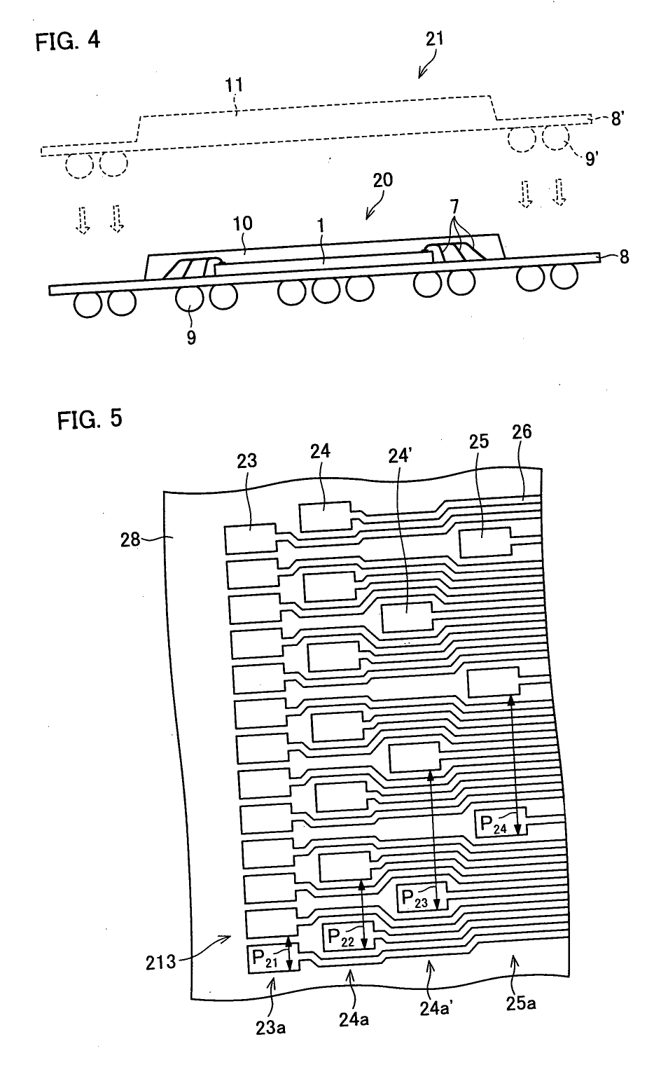

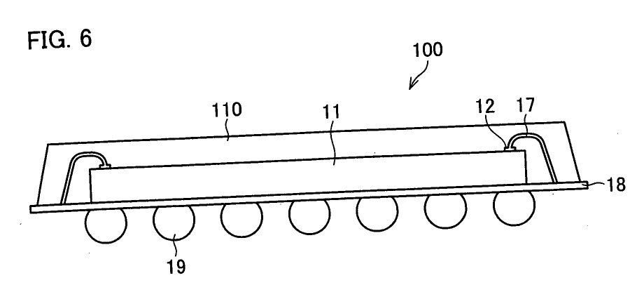

Next, with reference to FIG. 4, the following explains members provided in the present semiconductor device and structures thereof. FIG. 4 is a cross sectional view illustrating the structure of a semiconductor device including the wiring substrate (wiring substrate 8) illustrated in FIGS. 1(a) and 1(b).

The present semiconductor device has a structure in which a plurality of packages are laminated. Namely, as illustrated in FIG. 4, the present semiconductor device includes a lower semiconductor package 20 and an upper semiconductor package 21.

As illustrated in FIG. 4, the lower semiconductor package 20 includes a semiconductor chip 1, Au wires 7, a wiring substrate 8, solder balls 9, and sealing resin (a sealing section) 10. The semiconductor chip 1 is mounted on the wiring substrate 8. Further, the solder balls 9 acting as external connecting terminals are provided on the wiring substrate 8 so as to be positioned on a surface opposite to the surface on which the semiconductor chip 1 is mounted, and the solder balls 9 provide conduction with the wiring substrate 8.

Both sides of the wiring substrate 8 (the side on which the semiconductor chip 1 is mounted and the side on which the solder balls 9 are provided) have wiring patterns formed thereon. A VIA hole or VIA holes are provided in the wiring substrate 8 so as to provide conduction between the wiring patterns formed on the both sides. Conductors are provided inside the VIA hole or VIA holes.

The semiconductor chip 1 is fixed on the wiring substrate 8 via adhesive. The semiconductor chip 1 is connected with the wiring substrate 8 via the Au wires 7, and the semiconductor chip 1 is conductive with respect to the wiring substrate 8. Further, the semiconductor chip 1 and the Au wires 7 are sealed by the sealing resin 10. Further, the solder balls 9 acting as external connecting terminals are provided on the wiring substrate 8 so as to be positioned on the surface opposite to the surface on which the semiconductor chip 1 is mounted. In the lower semiconductor package 20, the area of the sealing resin 10 for sealing with resin is smaller than the size of the wiring substrate 8.

Further, in the upper semiconductor package 21, sealing resin 11 for sealing a semiconductor chip (not shown) and Au wires (not shown) is provided on a wiring substrate 8′.

Further, solder balls 9′ acting as external connecting terminals are provided on the wiring substrate 8′ so as to be positioned on a surface opposite to the surface on which the sealing resin 11 is provided, and the solder balls 9′ provide conduction with the wiring substrate 8′.

In a package in which packages are laminated, lands are provided on a substrate so as to be positioned on a surface where a semiconductor chip is mounted and so as to be positioned on an area outside a resin-sealed area on the surface, and the lands are used for mounting the package on the surface. Namely, in a case of a package in which a plurality of packages are laminated by connecting external terminals provided outside an area where a semiconductor chip is mounted, in order to provide electric conduction between an upper package and a lower package, it is necessary to provide lands for mounting the upper package, on an upper surface of the lower package so that the lands are positioned on locations corresponding to the solder balls 9′.

In the present semiconductor device, the wiring substrate 8 (wiring substrate 8′) may be a two-layered wiring substrate or a single-layered wiring substrate.

Further, an example of the wiring substrate 8 (wiring substrate 8′) is such that a substrate is made of an insulating material such as polymide and glass epoxy and copper foil is laminated on a front surface of the substrate. Further, the wiring substrate may be such that a front surface on a wiring pattern is coated via solder resist.

Further, the present semiconductor device may be arranged so as to be a laminating package by providing, on the outside of the resin-sealed area, lands used for laminating an upper package.

Particularly, in a case where the lands used for laminating an upper package are provided outside the resin-sealed section, the size of the resin-sealed area is limited, so that the arrangement of the present invention, in which wire bond terminals are provided in a staggered manner, is appropriate.

Further, in a package having many external terminals on a packaging substrate, it is effective to draw out drawn-out wirings from a surface on which wire bond terminals are provided. The reason is as follows: if there are many external terminals, then the pitch between the external terminals must be small so as to provide necessary number of external terminals in a package area. If the pitch between the external terminals becomes small, the number of wirings allowed to pass between the external terminals is reduced, so that it is difficult to extend, to the circumference of the package, the wirings drawn out toward the center of the package.

Further, the wiring pattern of the present semiconductor device is applicable to a semiconductor device having small chip size and many pins, other than a semiconductor device in which a plurality of packages are laminated.

Further, in a package whose resin-sealed area is limited by a package having many pins, the disposition of wire bond terminals according to the present embodiment allows fabrication of a substrate with stable qualities at lower cost. Particularly, the disposition is effective in a laminated package, which is expected to be widely used.

### Embodiment 2

The following explains another embodiment of the present invention.

Embodiment 1 explains the semiconductor device in which three columns of wire bond terminals are provided from the side of the pads formed on the semiconductor chip. However, the semiconductor device according to the present invention is not limited to the arrangement in which three columns of the wire bond terminals are provided from the side of the pads. Namely, the semiconductor device according to the present invention may be arranged so that n number of columns (n is an integer of 3 or greater) of wire bond terminals are provided so that the first column is the closest to pads of a semiconductor chip.

To be more specific, in a case where four columns of wire bond terminals are provided so that the first column is the closest to pads of a semiconductor chip, the ratio of the numbers of the wire bond terminals belonging to the first column to the fourth column, respectively, is 4:2:1:1 from the pads. At that time, the ratio of pitches of the wire bond terminals belonging to the first column to the fourth column, respectively, is 1:2:4:4 from the pads.

Further, in a case where five columns of wire bond terminals are provided so that the first column is the closest to pads of a semiconductor chip, the ratio of the numbers of the wire bond terminals belonging to the first column to the fifth column, respectively, is 8:4:2:1:1 from the pads. At that time, the ratio of pitches of the wire bond terminals belonging to the first column to the fifth column, respectively, is 1:2:4:8:8 from the pads.

Further, in a case where six columns of wire bond terminals are provided so that the first column is the closest to pads of a semiconductor chip, the ratio of the numbers of the wire bond terminals belonging to the first column to the six column, respectively, is 16:8:4:2:1:1 from the pads. At that time, the ratio of pitches of the wire bond terminals belonging to the first column to the six column, respectively, is 1:2:4:8:16:16 from the pads.

Namely, regardless of whether the number of columns of the wire bond terminals is 4, 5, or 6, the ratio of the numbers of the wire bond terminals belonging to outer three columns is 2:1:1 and the ratio of pitches of the wire bond terminals belonging to the outer three columns is 1:2:2. To be specific, in a case where five columns of the wire bond terminals are provided so that the first column is the closest to the pads of the semiconductor chip, the ratio of the number of the wire bond terminals belonging to the n-2ₜₕ column, the number of the wire bond terminals belonging to the n-1ₜₕ column, and the number of the wire bond terminals belonging to the nₜₕ column is 2:1:1. Further, the ratio of a pitch of the wire bond terminals belonging to the n-2ₜₕ column, a pitch of the wire bond terminals belonging to the n-1ₜₕ column, and a pitch of the wire bond terminals belonging to the nₜₕ column is 1:2:2.

Further, when a pitch between wire bond terminals belonging to the mₜₕ column (m is an integer of 3 or greater) out of the first column to the nₜₕ column is Pₘ, Pₘ is preferably set so that a relation represented by equation (1) as indicated below is established.
Pₘ=P₁×2^{m-1}(m=2, 3, . . . , n−1), Pₙ=P₁×2ⁿ⁻² (1)

Further, when the number of wire bond terminals belonging to the mₜₕ column out of the first column to the nₜₕ column is aₘ, aₘ is preferably set so that a relation represented by equation (2) as indicated below is established.
aₘ=aₘ₊₁+aₘ₊₂+ . . . +aₙ₋₁+aₙ (2)

By setting locations of the wire bond terminals belonging to the first column to the nₜₕ column, respectively, so that equations (1) and (2) are met, it is possible to draw out drawn-out wirings from all the wire bond terminals belonging to the first column to the nₜₕ column, respectively, toward the outside of the package.

As to the arrangement in which n number of columns (n is an integer of 3 or greater) of wire bond terminals are provided so that the first column is the closest to pads of a semiconductor chip, the present embodiment explains a case where four columns of the wire bond terminals are provided so that the first column is the closest to the pads of the semiconductor chip. FIG. 5 is a plan view illustrating the location of the wire bond terminals on a wiring substrate of the semiconductor device according to the present embodiment, and illustrates the wiring pattern of the wiring substrate.

As illustrated in FIG. 5, a wiring substrate 28 in the present semiconductor device includes a wiring pattern 213.

The wiring pattern 213 includes first wire bond terminals 23, second wire bond terminals 24, third wire bond terminals 24′, and fourth wire bond terminals 25. Further, a column 23a (first column) of the first wire bond terminals 23, a column 24a (second column) of the second wire bond terminals 24, a column 24a′ (third column) of the third wire bond terminals 24′, and a column 25a of the fourth wire bond terminals 25 are provided in this order so that the column 23a is the closest to pads of a semiconductor chip (not shown).

The first wire bond terminals 23, the second wire bond terminals 24, and the third wire bond terminals 24′, and the fourth wire bond terminals 25 are provided with predetermined pitches P₂₁, P₂₂, P₂₃, and P₂₄, respectively. Further, the ratio of the pitches P₂₁, P₂₂, P₂₃, and P₂₄ is 1:2:4:4.

Further, the ratio of the number of the wire bond terminals belonging to the column 23a, the number of the wire bond terminals belonging to the column 24a, the number of the wire bond terminals belonging to the column 24a′, and the number of the wire bond terminals belonging to the column 25a (the first wire bond terminals 23, the second wire bond terminals 24, the third wire bond terminals 24′, and the fourth wire bond terminals 25) is 4:2:1:1.

With the arrangement, the distance between the third wire bond terminals 24′ belonging to the column 24a′ and the distance between the fourth wire bond terminals 25 belonging to the column 25a are widened, so that it is possible to draw out a plurality of drawn-out wirings (seven drawn-out wirings) through a space between the wire bond terminals. Namely, with the location of the wire bond terminals in the present semiconductor device, it is possible to provide a space between the wire bond terminals, through which space the drawn-out wirings pass, unlike a conventional semiconductor device. Therefore, in the present semiconductor device, it is possible to efficiently draw out, toward the circumference of the package, drawn-out wirings from the wire bond terminals (the first wire bond terminals 23 belonging to the column 23a) provided closest to the semiconductor chip. As a result, it is possible to fabricate a wiring substrate with stable qualities at lower cost.

As a result, in the present semiconductor device, the drawn-out wirings 26 are respectively drawn out of the first wire bond terminals 23, the second wire bond terminals 24, the third wire bond terminals 24′, and the fourth wire bond terminals 25. The drawn-out wirings 26 from the wire bond terminals are drawn out toward the outside of the package. Therefore, in the present semiconductor device, with efficient wiring between the wire bond terminals in a case where wirings with electrolytic plating are impossible, it is possible to provide a substrate with stable qualities at lower cost.

The present invention is not limited to the above embodiments, and a variety of modifications are possible within the scope of the following claims, and embodiments obtained by combining technical means suitably changed within the scope of the claims are also within the technical scope of the present invention.

As described above, the semiconductor device or a wiring substrate according to the present invention is arranged so that: when a plurality of columns are numbered as being a first column to an nₜₕ column (n is an integer of 3 or greater) so that the first column is closest to the connecting terminals, ratio of pitches between wire bond terminals belonging to an n-2ₜₕ column, an n-1ₜₕ column, and an nₜₕ column, respectively, is 1:2:2. Further, the laminated semiconductor device according to the present invention has a structure in which a plurality of the semiconductor devices are laminated.

Therefore, it is possible to efficiently draw out, toward the circumference of the semiconductor device, the drawn-out wirings from the wire bond terminals provided on the connecting terminals. As a result, it is possible to fabricate a wiring substrate with stable qualities at lower cost.

Further, it is preferable to arrange the semiconductor device according to the present invention so that: when a pitch between wire bond terminals belonging to an mₜₕ column (m is an integer of 3 or greater) out of the first column to the nₜₕ column is Pₘ, Pₘ is set so that a relation represented by equation (1) is established.
Pₘ=P₁×2^{m-1}(m=2, 3, . . . , n−1), Pₙ=P₁×2ⁿ⁻² (1)

With the arrangement, the wire bond terminals belonging to the first column to the nₜₕ column, respectively, are disposed so as to meet equation (1), it is possible to provide all the wire bond terminals belonging to the first column to the nₜₕ column. Further, with the arrangement, it is possible to efficiently draw out, to the circumference of the semiconductor device, the drawn-out wirings from the wire bond terminals provided on the side of the connecting terminals. As a result, it is possible to fabricate a wiring substrate with stable qualities at lower cost.

Further, it is preferable to arrange the semiconductor device according to the present invention so that: ratio of numbers of the n-2ₜₕ column, the n-1ₜₕ column, and the nₜₕ column, respectively, is 2:1:1.

Further, it is preferable to arrange the semiconductor device according to the present invention so that: when the number of wire bond terminals belonging to the mₜₕ column out of the first column to the nₜₕ column is aₘ, aₘ is set so that a relation represented by equation (2) is established.
aₘ=aₘ₊₁+aₘ₊₂+ . . . +aₙ₋₁+aₙ (2)

Further, it is preferable to arrange the semiconductor device according to the present invention so that wire bond terminals belonging to a second column to the nₜₕ column, respectively, are provided so that: when a straight line is drawn between wire bond terminals which belong to the first column and which are adjacent to each other, there exists at least one straight line which passes through the wire bond terminals belonging to the second column to the nₜₕ column, respectively.

Namely, the arrangement is such that at least one of the wire bond terminals belonging to the second column to the nₜₕ column is disposed between the wire bond terminals belonging to the first column.

Particularly, it is preferable to arrange the semiconductor device according to the present invention so that wire bond terminals belonging to a second column to the nₜₕ column, respectively, are provided so that: when a straight line is drawn between wire bond terminals which belong to the first column and which are adjacent to each other, the straight line passes through only one wire bond terminal belonging to any one of the second column to the nₜₕ column.

The semiconductor device as set forth in claim 1, wherein the wire bond terminals belonging to the second column to the nₜₕ column are provided so as to be shifted by the pitch between the connecting terminals with respect to the wire bond terminal belonging to the first column.

With the arrangement, the pitch between bonding wires electrically connected with the wire bond terminals is comparatively close to the pitch between the connecting terminals provided on the semiconductor chip. This allows for reduction of the length of the bonding wires. As a result, the wire bond terminals are positioned comparatively close to the semiconductor element, so that it is possible to downsize the semiconductor device.

Particularly, in a case where the wire bond terminals belonging to the second column to the nₜₕ column are provided so that: when a straight line is drawn between the wire bond terminals which belong to the first column and are adjacent to each other, the straight line passes through only one wire bond terminal belonging to one of the second column to the nₜₕ column, bonding wires electrically connected with the wire bond terminals do not overlap each other.

It is preferable to arrange the semiconductor device according to the present invention so that: the wiring substrate includes a land section for being electrically connected with external connecting terminals and is sealed by a sealing member for sealing the semiconductor element and the bonding wires, and the land section is provided on a substrate surface so as to be positioned on an area other than an area sealed by the sealing member.

As described above, in the semiconductor device according to the present invention, it is possible to efficiently draw out, to the circumference of the semiconductor device, the drawn-out wirings from the wire bond terminals provided on the connecting terminals. Therefore, the semiconductor device according to the present invention is effectively applicable to a semiconductor device in which a land section for allowing electrical connection with external connecting terminals is provided on a substrate surface so as to be positioned on an area other than the area sealed by the sealing member. Note that, “substrate surface” means a surface of a wiring substrate, on which surface a semiconductor element is provided.

Further, it is preferable to arrange the wiring substrate according to the present invention so that ratio of numbers of the n-2ₜₕ column, the n-1ₜₕ column, and the nₜₕ column, respectively, is 2:1:1.

Further, it is preferable to arrange the wiring substrate according to the present invention so that: the wiring substrate includes a land section for being electrically connected with external connecting terminals and is sealed by a sealing member for sealing the semiconductor element and the bonding wires, and the land section is provided on a substrate surface so as to be positioned on an area other than an area sealed by the sealing member.

As described above, with the semiconductor device according to the present invention, it is possible to fabricate a wiring substrate with stable qualities at lower cost. Therefore, the semiconductor device is favorably applicable to semiconductor industries. Particularly, the present invention is applicable to a semiconductor device of package stack type, in which a semiconductor package is mounted on another semiconductor package.

The present invention is not limited to the above embodiments, and a variety of modifications are possible within the scope of the following claims, and embodiments obtained by combining technical means suitably changed within the scope of the claims are also within the technical scope of the present invention.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor device, comprising a semiconductor element and a wiring substrate on which a wiring pattern is formed,
said wiring pattern including wire bond terminals electrically connected, via bonding wires, with connecting terminals provided on the semiconductor element,
said wire bond terminals being disposed in a plurality of columns so as to face the connecting terminals,
wherein:
when the columns are regarded as a first column to an nₜₕ column (n is an integer of 3 or greater) so that the first column is closest to the connecting terminals,
a ratio of a pitch between wire bond terminals belonging to an n-2ₜₕ column, a pitch between wire bonding terminals belonging to an n-1ₜₕ column, and a pitch between wire bonding terminals belonging to an nₜₕ column is 1:2:2.

2. The semiconductor device as set forth in claim 1, wherein
Pₘ=P₁×2^{m-1}(m=2, 3, . . . , n−1), Pₙ=P₁×2ⁿ⁻² (1)
where Pₘ is a pitch between wire bond terminals belonging to an mₜₕ column (m is an integer of 3 or greater) out of the first column to the nₜₕ column.

3. The semiconductor device as set forth in claim 1, wherein a ratio of the number of wire bond terminals belonging to the n-2ₜₕ column, the number of wire bond terminals belonging to the n-1ₜₕ column, and the number of wire bond terminals belonging to the nₜₕ column is 2:1:1.

4. The semiconductor device as set forth in claim 1, wherein
aₘ=aₘ₊₁+aₘ₊₂+ . . . +aₙ₋₁+aₙ (2)
where aₘ is the number of wire bond terminals belonging to the mₜₕ column out of the first column to the nₜₕ column.

5. The semiconductor device as set forth in claim 1, wherein wire bond terminals belonging to a second column to the nₜₕ column, respectively, are provided so that: when a straight line is drawn between wire bond terminals which belong to the first column and which are adjacent to each other, there exists at least one straight line which passes through one or more wire bond terminals belonging to the second column to the nₜₕ column.

6. The semiconductor device as set forth in claim 1, wherein wire bond terminals belonging to a second column to the nₜₕ column, respectively, are provided so that: when a straight line is drawn between wire bond terminals which belong to the first column and which are adjacent to each other, the straight line passes through only one wire bond terminal belonging to any one of the second column to the nₜₕ column.

7. The semiconductor device as set forth in claim 1, wherein wire bond terminals belonging to a second column to the nₜₕ column are provided so as to be shifted, by a pitch between the connecting terminals, with respect to wire bond terminals belonging to the first column.

8. The semiconductor device as set forth in claim 1, wherein:
the wiring substrate includes a land section for allowing electrical connection with external connecting terminals and is sealed by a sealing member for sealing the semiconductor element and the bonding wires, and
the land section is provided on a substrate surface so as to be positioned on an area other than an area sealed by the sealing member.

9. A laminated semiconductor device, in which a plurality of semiconductor devices are laminated,
each of said semiconductor devices including a semiconductor element and a wiring substrate on which a wiring pattern is formed,
said wiring pattern including wire bond terminals electrically connected, via bonding wires, with connecting terminals provided on the semiconductor element,
said wire bond terminals being disposed in a plurality of columns so as to face the connecting terminals,
wherein:
when the columns are regarded as a first column to an nₜₕ column (n is an integer of 3 or greater) so that the first column is closest to the connecting terminals,
a ratio of pitches among wire bond terminals belonging to an n-2ₜₕ column, an n-1ₜₕ column, and an nₜₕ column, respectively, is 1:2:2.

10. The laminated semiconductor device as set forth in claim 9, wherein:
the wiring substrate includes a land section for allowing electrical connection with external connecting terminals, and
the land section is provided so as to allow conduction of the laminated semiconductor devices.

11. A wiring substrate, having a wiring pattern formed thereon, said wring pattern including wire bond terminals for being electrically connected with connecting terminals provided on a semiconductor element mounted on the wiring substrate,
said wire bond terminals being disposed in a plurality of columns on the wiring substrate so as to face the connecting terminals,
wherein:
when the columns are regarded as a first column to an nₜₕ column (n is an integer of 3 or greater) so that the first column is closest to the connecting terminals,
a ratio of a pitch between wire bond terminals belonging to an n-2ₜₕ column, a pitch between wire bond terminals belonging to an n-1ₜₕ column, and a pitch between wire bond terminals belonging to an nₜₕ column is 1:2:2.

12. The wiring substrate as set forth in claim 11, wherein a ratio of the number of wire bonding terminals belonging to the n-2ₜₕ column, the number of wire bond terminals belonging to the n-1ₜₕ column, and the number of wire bond terminals belonging to the nₜₕ column is 2:1:1.

13. The wiring substrate as set forth in claim 11, comprising a land section for allowing electrical connection with external connecting terminals, said wiring substrate being sealed by a sealing member for sealing the semiconductor element and the bonding wires, wherein
the land section is provided on a substrate surface so as to be positioned on an area other than an area sealed by the sealing member.
